(19) United States
(12) Patent Application Publication
(10) Pub. No.: US 2026/0024609 A1
(43) Pub. Date: Jan. 22, 2026

(54) MEMORY DEVICE INCLUDING ANTI-FUSE CELL ARRAY IN CELL ARRAY STRUCTURE

(71) Applicant: SAMSUNG ELECTRONICS CO., LTD., Suwon-si (KR)

(72) Inventor: Sukhyun Lim, Suwon-si (KR)

(73) Assignee: SAMSUNG ELECTRONICS CO., LTD., Suwon-si (KR)

(21) Appl. No.: 19/206,608

(22) Filed: May 13, 2025

(30) Foreign Application Priority Data
Jul. 22, 2024 (KR) 10-2024-0096481

(51) Int. Cl. G11C 29/44; H01L 23/00; H01L 25/065; H01L 25/18; H10B 12/00; H10B 80/00

(52) U.S. Cl. CPC G11C 29/4401; H01L 24/08; H01L 25/0657; H01L 25/18; H10B 12/315; H10B 12/482; H10B 80/00; H01L 2224/08145; H01L 2924/1431; H01L 2924/1436

(57) ABSTRACT

Provided is a memory device including an anti-fuse cell array in a cell array structure. The memory device includes a core peripheral circuit structure including a first bonding metal pad, and a cell array structure arranged above the core peripheral circuit structure and including a second bonding metal pad in contact with the first bonding metal pad. The cell array structure includes a plurality of memory blocks and a plurality of anti-fuse cells. The core peripheral circuit structure further includes a repair circuit connected to the anti-fuse cells, and the repair circuit is configured to control each anti-fuse cell to be programmed, and perform, based on fuse data of the anti-fuse cells received through the first and second bonding metal pads connected to the anti-fuse cells, a repair operation of replacing a defective memory cell in the memory cell array area with a redundancy memory cell.

### CROSS-REFERENCE TO RELATED APPLICATION

This application is based on and claims priority under 35 U.S.C. § 119 to Korean Patent Application No. 10-2024-0096481, filed on Jul. 22, 2024, in the Korean Intellectual Property Office, the disclosure of which is incorporated by reference herein in its entirety.

### BACKGROUND

The present application relates to semiconductor memory devices, and more particularly, to memory devices including an anti-fuse cell array in a cell array structure in order to reduce a chip size of the memory devices having a cell over periphery (COP) structure.

Recently, with the multi-functionalization of information communication devices, high capacity and high integration of memory devices have been required. In accordance with the reduction of memory cell sizes for high integration, operation circuits and/or line structures included in a memory device for operational and electrical connection of the memory device are becoming more complex. In order to improve the storage capacity and the degree of integration of memory devices, a vertical channel transistor, which is vertically formed on a semiconductor substrate, has been introduced, rather than a planar channel transistor, which is planarly formed on a semiconductor substrate.

To process a large volume of data stably and quickly in real time, the demand for a high-capacity dynamic random-access memory (DRAM) has increased. However, performance quality of DRAM may change over time. In a memory system, functions of reliability, availability, and serviceability (RAS) with respect to DRAM may be expected. Thus, a DRAM may perform a repair operation in which one or more defective memory cells in a memory cell array (MCA) are detected in a test operation on the MCA and each of the one or more defective memory cells are replaced with a redundancy memory cell. Here, the DRAM may include a repair circuit for performing the repair operation. The repair circuit may store a defective address of the defective memory cell(s) detected in the test operation and may command the repair operation to be performed on the defective address. The repair circuit may store the defective address in an anti-fuse cell array.

A DRAM may have a cell over periphery (COP) structure including a cell array structure and a core peripheral circuit structure perpendicularly overlapping each other. The cell array structure may include a memory cell array including a plurality of memory cells including a vertical channel transistor and a capacitor, and the core peripheral circuit structure may include a row decoder, a column decoder, and peripheral circuits including a repair circuit. As memory process shrinkage continues, a ratio of a core peripheral circuit area to a memory cell array area may increase. Thus, a DRAM chip size of the COP structure is a dominant factor of the core peripheral circuit area.

In order to reduce the DRAM chip size, it is necessary to reduce the area of the core peripheral circuit area. Reducing the area occupied by the repair circuit would be helpful in reducing the DRAM chip size.

### SUMMARY

Embodiments provide memory devices including an anti-fuse cell array in a cell array structure of the memory devices having a COP structure.

According to an aspect of the disclosure, a memory device includes: a core peripheral circuit structure including a first bonding metal pad; and a cell array structure arranged above the core peripheral circuit structure to vertically overlap the core peripheral circuit structure, and including a second bonding metal pad in contact with the first bonding metal pad, wherein the cell array structure comprises: a memory cell array area including a plurality of memory blocks, and an anti-fuse cell array area including a plurality of anti-fuse cells and arranged in a different area from the memory cell array area, the core peripheral circuit structure further comprises a repair circuit connected to first signal lines and the plurality of anti-fuse cells of the anti-fuse cell array area, and the repair circuit comprises: an anti-fuse logic circuit configured to control each anti-fuse cell to be programmed, receive information of the plurality of anti-fuse cells through the first and second bonding metal pads connected to the plurality of anti-fuse cells, and output fuse data, and a redundancy logic circuit configured to receive first fuse data through the first signal lines connected to the anti-fuse logic circuit and perform, based on the first fuse data, a repair operation of replacing a defective memory cell in the memory cell array area with a redundancy memory cell.

According to an aspect of the disclosure, a memory device includes: a core peripheral circuit structure including a first bonding metal pad; and a cell array structure arranged above the core peripheral circuit structure to vertically overlap the core peripheral circuit structure, and including a second bonding metal pad in contact with the first bonding metal pad, wherein the cell array structure comprises: first signal lines; a memory cell array area including a plurality of memory blocks; and an anti-fuse cell array area including a plurality of anti-fuse cells and arranged in a different area from the memory cell array area, the core peripheral circuit structure further comprises a repair circuit connected to second signal lines and the plurality of anti-fuse cells, and the repair circuit comprises: an anti-fuse logic circuit configured to control each anti-fuse cell to be programmed, receive information of the plurality of anti-fuse cells through the first and second bonding metal pads connected to the plurality of anti-fuse cells and output fuse data, and provide the fuse data to the first signal lines of the cell array structure through the first and second bonding metal pads, and a redundancy logic circuit configured to receive first fuse data through the first and second bonding metal pads connected to the first signal lines of the cell array structure and the second signal lines of the core peripheral circuit structure and perform, based on the first fuse data, a repair operation of replacing a defective memory cell in the memory cell array area with a redundancy memory cell.

According to an aspect of the disclosure, a memory device includes: a core peripheral circuit structure including a first bonding metal pad; and a cell array structure arranged above the core peripheral circuit structure to vertically overlap the core peripheral circuit structure, and including a second bonding metal pad in contact with the first bonding metal pad, wherein the cell array structure comprises: a memory cell array area including a plurality of memory blocks; and an anti-fuse cell array area including a plurality of anti-fuse cells and arranged in a different area from the memory cell array area, and the core peripheral circuit structure further comprises a test mode register set (TMRS) configured to store, based on first fuse data stored in the plurality of anti-fuse cells of the anti-fuse cell array area, test options for a test operation of the memory device.

### BRIEF DESCRIPTION OF THE DRAWINGS

The above and/or other aspect will be more clearly understood from the following detailed description of embodiments taken in conjunction with the accompanying drawings, in which:

FIG. 1 is a conceptual diagram of a test system for testing a memory device, according to embodiments;

FIGS. 2 and 3 are conceptual diagrams of a memory device according to embodiments;

FIG. 4 is a diagram for describing a repair circuit according to embodiments;

FIGS. 5, 6, and 7 are diagrams for describing a memory device including the repair circuit of FIG. 4;

FIGS. 8A, 8B, and 9 are diagrams for describing a structure of a memory device according to embodiments;

FIGS. 10 and 11 are diagrams for describing an anti-fuse cell according to embodiments; and

FIG. 12 is a block diagram of a system of an electronic device including a memory device according to embodiments.

### DETAILED DESCRIPTION

According to one or more embodiments, a memory device described herein may be a dynamic random-access memory (DRAM) having a cell over periphery (COP) structure including a cell array structure and a core peripheral circuit structure perpendicularly overlapping each other. The cell array structure may include a memory cell array including a plurality of memory cells including a vertical channel transistor and a capacitor and formed at a point at which word lines cross bit lines, and the memory cell array may include a plurality of memory blocks (sometimes referred to as memory banks). The core peripheral circuit structure may include a row decoder, a column decoder, and peripheral circuits including a repair circuit. The row decoder may decode a row address and select a word line corresponding to the row address and may apply a word line driving voltage having a high voltage level to the selected word line. The column decoder may select bit lines corresponding to a column address from among bit lines of memory cells connected to the selected word line. Data of the selected bit lines from among data of memory cells sensed by a sense amplifier circuit connected to the bit lines, may be output to a memory controller through (a) data pad(s). The repair circuit may store a defective address of a defective memory cell detected in a test operation of the memory device and may perform a repair operation on the defective address. The repair circuit may perform the repair operation to replace a defective word line selected by the defective address with a redundancy word line or to replace a defective bit line selected by the defective address with a redundancy bit line. Hereinafter, provided is a memory device, in which an anti-fuse cell array, which is part of a repair circuit, is arranged in an area other than a memory cell array area in a cell array structure, to reduce a chip size of the memory device as well as improve the yield rate and reliability of the memory device.

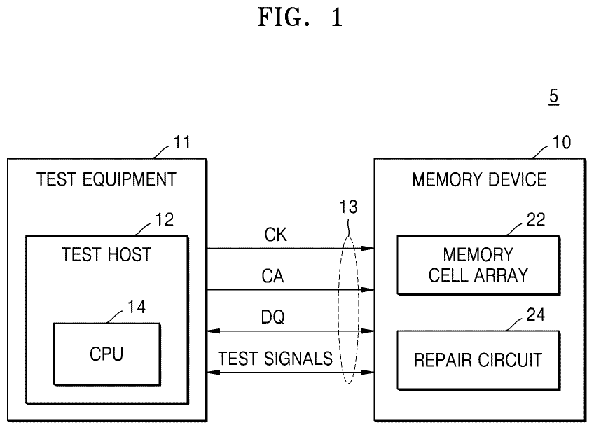

FIG. 1 is a conceptual diagram of a test system 5 for testing a memory device 10, according to embodiments.

Referring to FIG. 1, a method, performed by test equipment 11, of testing the memory device 10, in the test system 5, is illustrated. The test equipment 11 may include a test host 12 configured to test the memory device 10 that is a device under test (DUT). The test host 12 may include at least one processor such as a central processing unit (CPU) 14 configured to control hardware, software, and firmware to perform a test operation on the memory device 10. The test host 12 may transmit test signals of the CPU 14 to the memory device 10 or transmit a performance result value with respect to the test signals output from the memory device 10 to the CPU 14.

The test host 12 may be implemented as a test program. The test program may include a test algorithm or pattern for performing the test operation. For example, after the test host 12 stores predetermined data in a storage area of the DUT, that is, a memory cell array 22 of the memory device 10, the test host 12 may read the stored data, and then, may determine pass/fail of a test operation according to whether or not the read data corresponds to predetermined data. The test host 12 may measure a change in voltage/current/frequency with respect to the memory device 10 under various driving conditions and may test whether the change is within a permitted range. The test host 12 may test a predetermined circuit operation of the memory device 10, and in particular, may test a repair circuit 24 to detect a defect of the repair circuit 24.

The test host 12 may test the memory device 10 through a channel 13. The channel 13 may include a bus and/or signal lines for physically or electrically connecting the test host 12 with the memory device 10. For example, a clock CK may be received by the memory device 10 through a clock bus, a command address CA may be received by the memory device 10 through a command address bus, and data DQ may be provided between the test host 12 and the memory device 10 through a data bus. Also, test signals may be provided between the test host 12 and the memory device 10 through test signal lines. For brevity of the drawing, it is illustrated that signals are transmitted between the test host 12 and the memory device 10 through one signal line. However, actually, each bus may include one or more signal lines through which signals are provided.

The test host 12 may provide a command to the memory device 10 to test a memory operation. Examples of a memory command may include, but are not limited to, a timing command for controlling timings of various operations, an access command for accessing a memory, for example, a read command for performing a read operation and a write command for performing a write operation, a mode register write and read command for performing a write and read operation of a mode register, a repair command, etc.

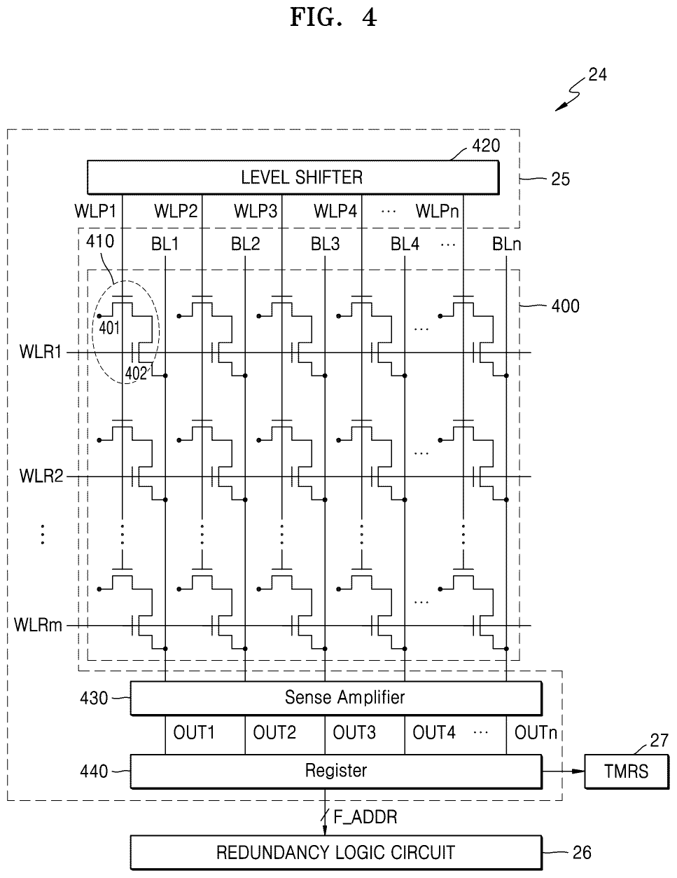

During a test, when a write command and a related address are provided to the memory device 10 by the test host 12, the memory device 10 may receive the write command and the related address and perform a write operation to write write data from the test host 12 in a memory position corresponding to the related address. The write data may be provided to the memory device 10 by the test host 12 according to a timing related to reception of the write command. For example, the timing may be based on a write latency (WL) value indicating the number of clock cycles after the write command, when the write data is provided to the memory device 10 by the test host 12. The WL value may be programmed in a mode register set MRS of the memory device 10 by the test host 12. As known, the MRS of the memory device 10 may be programmed with information for setting various operation modes and/or for selecting an attribute for a memory operation. Also, information for the test operation of the memory device 10 may be stored in a test mode register set (TMRS) 27 (see FIG. 4).

During a test, when a read command and a related address are provided to the memory device 10 by the test host 12, the memory device 10 may receive the read command and the related address and perform a read operation to output read data from a memory position corresponding to the related address. The read data may be provided to the test host 12 by the memory device 10 according to a timing related to reception of the read command. For example, the timing may be based on a read latency (RL) value indicating the number of clock cycles after the read command, when the read data is provided to the test host 12 by the memory device 10. The RL value may be set in the memory device by the test host 12. For example, the RL value may be programmed in the MRS of the memory device 10.

The test host 12 may provide a repair command and a defective address to the memory device 10. The repair command may be a command to instruct storage of a defective address detected in the memory device 10 in a nonvolatile memory (for example, an anti-fuse cell array 400 (see FIG. 4)) in the memory device 10 and instruct performance of a repair operation on the defective address. In response to the repair command, the memory device 10 may perform a repair operation to replace a defective word line selected by the defective address with a redundancy word line or to replace a defective bit line selected by the defective address with a redundancy bit line.

The memory device 10 may include the memory cell array 22 and the repair circuit 24. The memory cell array 22 may include a plurality of rows, a plurality of columns, and a plurality of memory cells formed at points at which the rows cross the columns. The memory cell array 22 may include redundancy rows and/or redundancy columns to which redundancy memory cells are connected, wherein the redundancy memory cells are configured to repair a defective memory cell, when a defect or error occurs in a memory cell.

The repair circuit 24 may be configured to repair the defective memory cells detected in the memory cell array 22 by using the redundancy memory cells. The repair circuit 24 may repair defective cells detected through an electrical die sorting (EDS) test after a semiconductor manufacturing process of the memory device 10. Also, the repair circuit 24 may perform a post package repair operation to repair defective memory cells occurring during a package/module/mount test of the memory device 10 by using the redundancy memory cells.

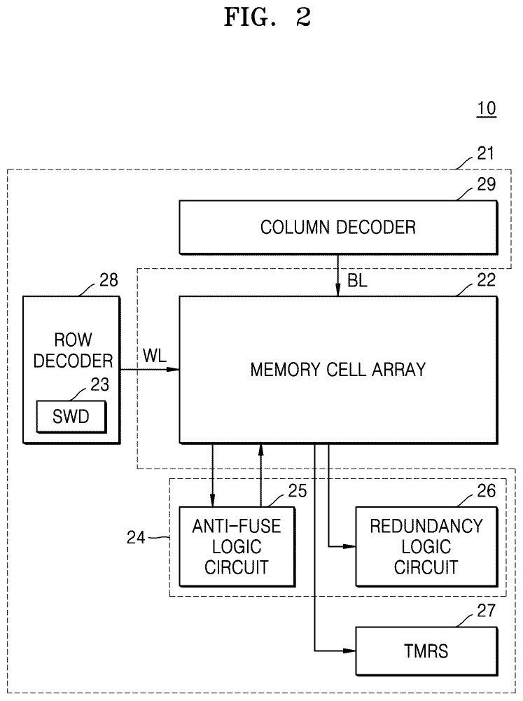

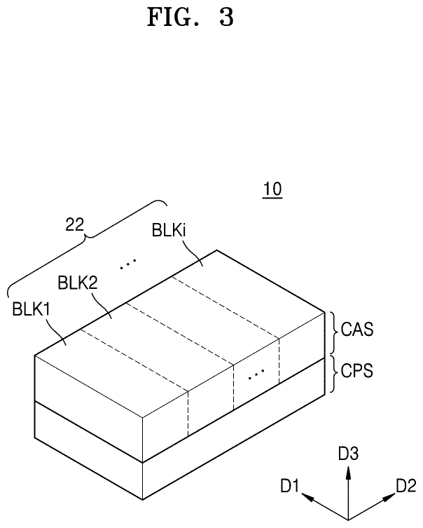

FIGS. 2 and 3 are conceptual diagrams of the memory device 10, according to embodiments. FIG. 3 is a diagram for describing a semiconductor structure of the memory device 10 of FIG. 2. For convenience of understanding, things described as an upper/lower surface, an upper/lower portion, above/below, right/left, etc. are based on directions illustrated in the drawings referred to. Thus, the same surface may be referred to as either of an upper surface and a lower surface, depending on the direction illustrated in the drawing.

Referring to FIG. 2, the memory device 10 may include a core peripheral circuit 21 and the memory cell array 22, and the core peripheral circuit 21 may include a row decoder 28, a sense amplifier circuit, the repair circuit 24, and a TMRS 27. The core peripheral circuit 21 may further include a command address circuit, a column decoder 29, a voltage generation circuit, a control logic circuit, an input and output gating circuit, a data input and output circuit, etc. According to embodiments, the memory device 10 may be a DRAM including a plurality of memory cells including a vertical channel transistor and a capacitor. Hereinafter, “the memory device” refers to a DRAM.

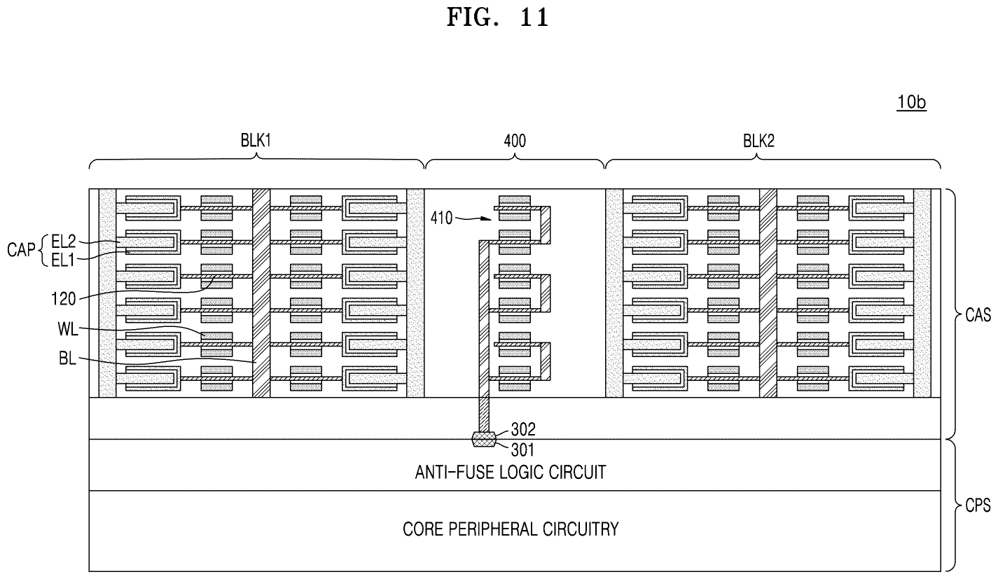

The memory cell array 22 may be connected to the row decoder 28 through a plurality of word lines WL and may be connected to the column decoder 29 through a plurality of bit lines BL. The memory cell array 22 may include the plurality of word lines WL, the plurality of bit lines BL, and a plurality of memory cells formed at points at which the plurality of word lines WL cross the plurality of bit lines BL. The memory cell array 22 may be divided into a plurality of memory blocks BLK1 to BLKi (i is an integer that is 2 or greater (see FIG. 2)). The memory cell array 22 may include the plurality of word lines WL and the plurality of bit lines BL that are connected to the memory cells. Each memory cell may be formed of a cell transistor and a cell capacitor, and the cell transistor may be realized as a cell structure CS described with reference to FIG. 11 and the cell capacitor may be realized as a capacitor structure DSP. A gate of the cell transistor may be connected to one of the plurality of word lines WL. An end of the cell transistor may be connected to one of the plurality of bit lines BL. The cell capacitor may store charges of a capacitance corresponding to single-bit data or multi-bits data.

The command address circuit may receive, from a memory controller connected to the memory device 10, a command and an address received together with the command, and may capture a block selection signal for selecting a memory block on which the command is to be performed, a row address, and a column address. The command address circuit may provide the received row address to the row decoder 28 and the received column address to the column decoder 29. The row decoder 28 may select a word line WL corresponding to the row address with respect to a memory block selected from among the plurality of memory blocks BLK1 to BLKi. The row decoder 28 may include a main word line driver circuit and a sub-word line driver circuit 23. The main word line driver circuit may be commonly connected to the memory blocks BLK1 to BLKi, and the sub-word line driver circuit 23 may be connected to each of the memory blocks BLK1 to BLKi. The main word line driver circuit may generate main word driving signals based on signals of a most significant bit (MSB) group from among row address signals and may generate sub-word line driving signals based on signals of a least significant bit (LSB) group from among the row address signals. The sub-word line driver circuit 23 may select any one of the word lines of the memory block selected based on the main word line driving signals and the sub-word line driving signals and may activate the selected word line to be a high-voltage level.

The voltage generation circuit may generate various internal voltages for driving circuits of the memory device 10. The voltage generation circuit may generate a high voltage, a negative voltage, an internal power voltage, a bit line pre-charge voltage, a reference voltage, a bulk bias voltage, etc. by using power voltage (for example, voltage drain drain (VDD)) applied from the outside of the memory device 10. The control logic circuit may control general operations of the memory device 10. The control logic circuit may generate control signals to perform a write operation, a read operation, and/or a repair operation of the memory device 10. The control logic circuit may include a mode register for setting a plurality of operational options of the memory device 10 and a command decoder for decoding a command received from the memory controller.

The sense amplifier circuit may sense data stored in the memory cell and transmit the sensed data to the data input and output circuit to be output to the memory controller through (a) data pad(s). The data input and output circuit may receive, from the memory controller, data to be written to the memory cells, through the data pad(s), and may transmit the received data to the memory cell array 22. The input and output gating circuit may output read data by using a data line amplifier configured to receive and amplify data sensed by the sense amplifier circuit. The read data may be output to the memory controller through the data pad(s). The input and output gating circuit may include a column selection circuit, an input data mask logic, read data latches, and/or a write driver, together with circuits for gating input and output data.

Referring to FIG. 3, the memory device 10 may include a cell array structure CAS and a core peripheral circuit structure CPS overlapping each other in a vertical direction (a D3 direction). The cell array structure CAS may include the memory cell array 22 of FIG. 2, and the core peripheral circuit structure CPS may include the core peripheral circuit 21 of FIG. 2.

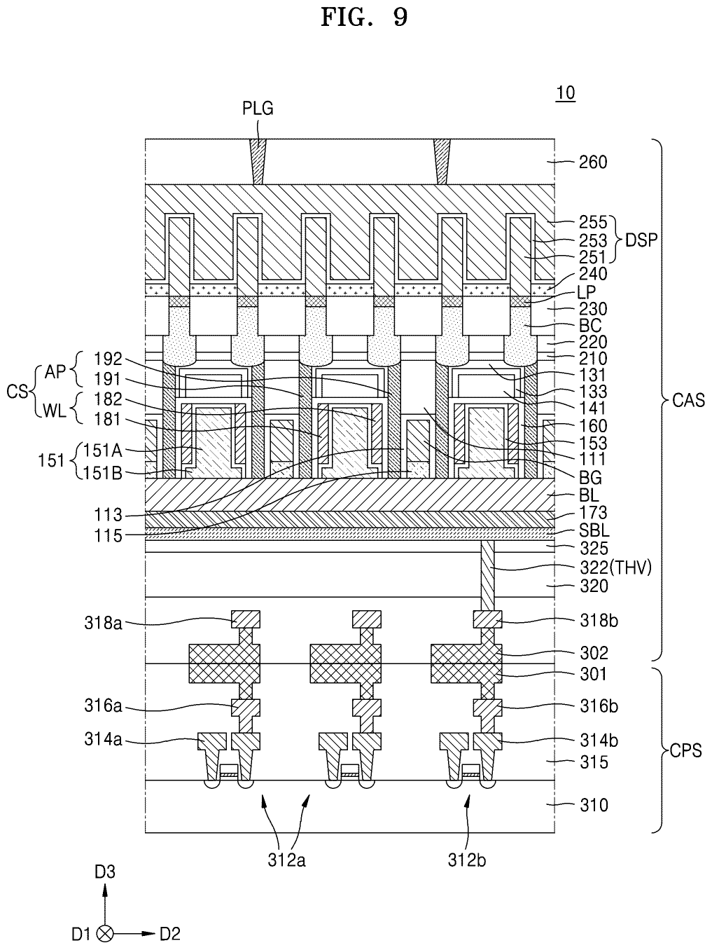

The cell array structure CAS may include a plurality of memory blocks BLK1, BLK2, . . . , and BLKi (i is a positive integer). The plurality of memory blocks BLK1, BLK2, . . . , and BLKi may include a plurality of memory cells including a vertical channel transistor and a capacitor. The core peripheral circuit structure CPS may include a semiconductor substrate, and the core peripheral circuit 21 may be formed by forming, on the semiconductor substrate, semiconductor devices, such as transistors, and a pattern for interconnecting the devices. After the core peripheral circuit 21 is formed in the core peripheral circuit structure CPS, the cell array structure CAS including the memory cell array 22 may be formed, and patterns (for example, bonding metal pads 301 and 302 of FIG. 9) for electrically connecting the word lines WL and the bit lines BL of the memory cell array 22 to the core peripheral circuit 21 formed in the core peripheral circuit structure CPS, may be formed. The cell array structure CAS and the core peripheral circuit structure CPS will be described in detail with reference to FIGS. 4 to 11.

FIG. 4 is a diagram for describing the repair circuit 24 according to embodiments.

Referring to FIGS. 1 and 4, the repair circuit 24 may receive and store, in a fuse cell array 400, defective address information provided from the test host 12 and/or information (sometimes, called as a test option) for a test operation of the memory device 10. The repair circuit 24 may include the fuse cell array 400 in which a plurality of anti-fuse cells 410 are arranged, an anti-fuse logic circuit 25, and a redundancy logic circuit 26. The anti-fuse logic circuit 25 may include a level shifter 420 configured to generate a high voltage for changing a resistance state of the anti-fuse cells 410 and a sense amplifier 430 configured to sense/amplify information stored in the fuse cell array 400. Also, a register portion 440 configured to store fuse data, which is generated by reading the information stored in the fuse cell array 400, may be included in the anti-fuse logic circuit 25.

The fuse cell array 400 may include a plurality of fuse cells and each fuse cell may store information. The fuse cell array 400 may include the anti-fuse cells 410, and an anti-fuse has a characteristic in which a state thereof changes from high resistance to low resistance due an electrical signal (for example, a high voltage signal). The fuse cell array 400 may be interchangeably referred to as an anti-fuse cell array 400. Also, information stored in the anti-fuse cell or data read from the anti-fuse cell may be referred to as fuse data. According to embodiments, the fuse cell array 400 may include a laser fuse, the connection of which is controlled by laser irradiation, or may include an electrical fuse, the connection of which is controlled by an electrical signal. The fuse cell array 400 may be implemented as any one of the plurality of types as described above.

The anti-fuse cell array 400 may have an array structure in which the anti-fuse cells 410 are arranged at positions at which a plurality of rows cross a plurality of columns. For example, when the anti-fuse cell array 400 has m rows and n columns, the anti-fuse cell array 400 may have m*n anti-fuse cells 410. The anti-fuse cell array 400 may include m first word lines WLR1 to WLRm for accessing the anti-fuse cells 410 arranged in the m rows, n second word lines WLP1 to WLPn for programming (sometimes, called as rupturing) the anti-fuse cells 410 arranged to correspond to the n columns, and n bit lines BL1 to BLn arranged to correspond to the n columns to transmit information read from the anti-fuse cells 410.

One anti-fuse cell 410 may be formed by one anti-fuse device 401 and one selection transistor 402 which are combined with each other. The anti-fuse device 401 may be realized by using a metal-oxide semiconductor field-effect transistor (MOSFET). A gate electrode of the anti-fuse device 401 may receive a high voltage of the second word lines WLP1 to WLPn, an end of the anti-fuse device 401 may be connected to an end of the selection transistor 402, and the other end of the anti-fuse device 401 may be in a floating state. A gate electrode of the selection transistor 402 may be connected to the first word lines WLR1 to WLRm, and an end of the selection transistor 402 may be connected to the bit lines BL1 to BLn. An insulation breakdown operation of a dielectric layer of the anti-fuse device 401 may occur according to voltage conditions of the first word lines WLR1 to WLRm, the second word lines WLP1 to WLPn, and the bit lines BL1 to BLn, and according to the insulation breakdown operation of the dielectric layer of the anti-fuse device 401, a programming operation may be performed.

The anti-fuse cell array 400 may be programmed by changing a state of the anti-fuse cell 410 by applying, to the anti-fuse cell array 400, a voltage level of the second word lines WLP1 to WLPm provided from the level shifter 420. The anti-fuse cell 410 may store information by being changed, via the programming operation, to a low resistance state from a high resistance state. The anti-fuse cell 410 may have a structure including two conductive layers and a dielectric layer therebetween, that is, a capacitor structure, and may be programmed via the insulation breakdown of the dielectric layer by applying a high voltage between the two conductive layers. According to the characteristic of the array structure, the anti-fuse cell 410 may be randomly programmed and/or accessed via driving of the first word lines WLR1 to WLRm, the second word lines WLP1 to WLPn, and the bit lines BL1 to BLn.

After the anti-fuse cell array 400 is programmed, a read operation on the anti-fuse cell array 400 may be performed, when the memory device 10 is started to be driven. The read operation on the anti-fuse cell array 400 may be simultaneously performed when the memory device 10 is driven or may be performed after a predetermined time period after the memory device 10 is started to be driven. A word line selection signal may be provided through the first word lines WLR1 to WLRm of the anti-fuse cell array 400, and information stored in a selected anti-fuse cell 410 may be provided to the sense amplifier 430 through the bit lines BL1 to BLn. For example, by sequentially driving the first word lines WLR1 to WLRm, the anti-fuse cells 410 in a first row to an mth row of the anti-fuse cell array 400 may be sequentially accessed. The information of the anti-fuse cells 410 sequentially accessed may be provided to the sense amplifier 430. The sense amplifier 430 may include one or more sense amplifier circuits. For example, when the anti-fuse cell array 400 has n columns, the sense amplifier 430 may include n sense amplifier circuits, according to the n columns of the anti-fuse cell array 400. The n sense amplifier circuits may be connected to the n bit lines BL1 to BLn, respectively.

The sense amplifier 430 may output the information accessed at the anti-fuse cell array 400 by sensing/amplifying the information accessed from the anti-fuse cell array 400. Fuse data OUT1 to OUTn output by the sense amplifier 430 may be provided to the register portion 440. The register portion 440 may receive the fuse data OUT1 to OUTn in row units of the anti-fuse cell array 400. For example, when any one row of the anti-fuse cell array 400 is selected, the fuse data OUT1 to OUTn from the anti-fuse cell 410 connected to the word line of the selected row may be provided to the register portion 440 in parallel.

The fuse data OUT1 to OUTn stored in the register portion 440 may include information for a repair operation, for example, a defective address F_ADDR referring to a defective row address and/or a defective column address. The defective address F_ADDR may be provided to the redundancy logic circuit 26. The redundancy logic circuit 26 may perform a repair operation so that a redundancy row address is selected instead of the defective row address. The redundancy logic circuit 26 may inactivate a word line corresponding to the defective row address and may instead activate a redundancy word line corresponding to the redundancy row address, and thus, redundancy memory cells corresponding to the redundancy row address may be selected instead of the memory cells corresponding to the defective row address. The redundancy logic circuit 26 may perform a repair operation so that a redundancy column address is selected instead of the defective column address. The redundancy logic circuit 26 may not select a bit line corresponding to the defective column address and may instead select a redundancy bit line corresponding to the redundancy column address, and thus, redundancy memory cells corresponding to the redundancy column address may be selected instead of the memory cells corresponding to the defective column address.

The fuse data OUT1 to OUTn stored in the register portion 440 may be the information for a test operation of the memory device 10. For example, the information for a test operation may include test patterns for detecting a defective cell in the memory cell array 22 and/or design for test (DFT) test patterns for the efficiency of test. The test patterns may include various test vectors which may be used to detect specific faults and structural defects and which may have high fault coverage.

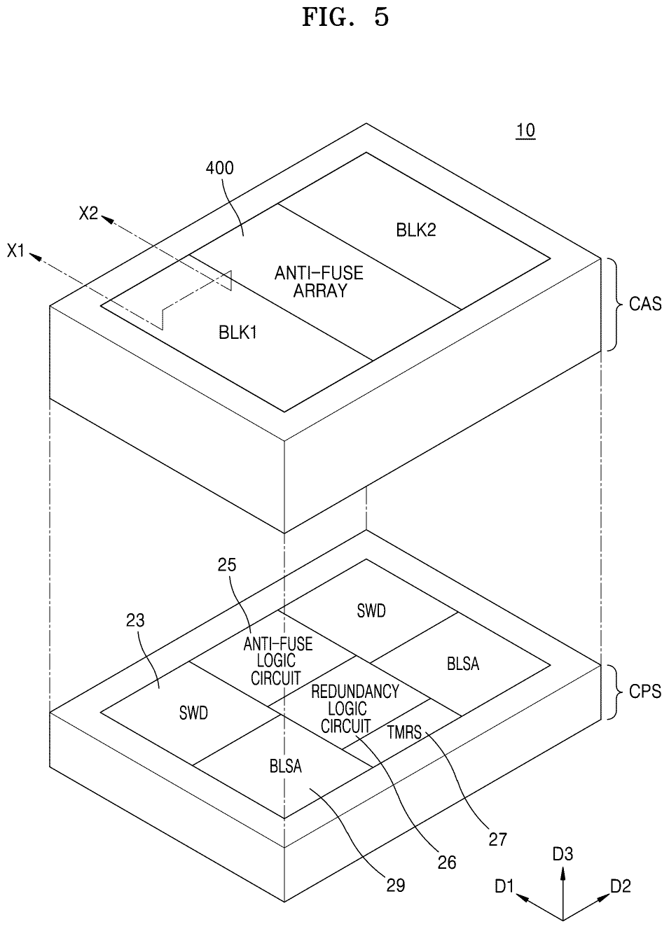

FIGS. 5, 6, and 7 are diagrams to describe memory devices 10, 10a, and 10b including the repair circuit 24 of FIG. 4. Hereinafter, subscripts attached to the same reference numeral in different drawings (for example, a of 10a and b of 10b) are used to distinguish a plurality of components having substantially the same or same functions from one another. With respect to the memory devices 10a and 10b, the same descriptions as the memory device 10 are not repeated.

Referring to FIG. 5 in relation to FIG. 4, the memory device 10 may include the cell array structure CAS and the core peripheral circuit structure CPS overlapping each other in a third direction (the D3 direction). The cell array structure CAS may include a first memory block BLK1 and a second memory block BLK2 and may include the anti-fuse cell array 400 between the first memory block BLK1 and the second memory block BLK2. The anti-fuse cell array 400 may be arranged in an area other than an area of the memory cell array 22, that is, in an empty area of the cell array structure CAS, in which the memory cell array 22 is not formed.

The core peripheral circuit structure CPS may include the sub-word line driver circuit 23 and the column decoder 29 which correspond to the first memory block BLK1 and the sub-word line driver circuit 23 and the column decoder 29 which correspond to the second memory block BLK2, in an area overlapping the first memory block BLK1 and an area overlapping the second memory block BLK2, respectively. The core peripheral circuit structure CPS may include the anti-fuse logic circuit 25, the redundancy logic circuit 26, and the TMRS 27 in an area overlapping the anti-fuse cell array 400.

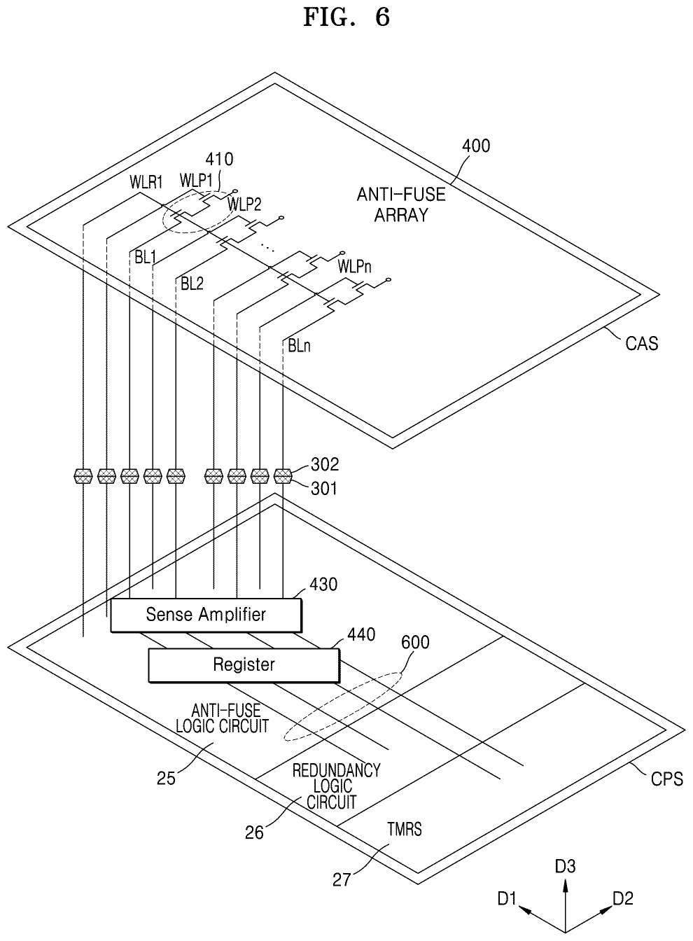

Referring to FIG. 6, in the cell array structure CAS of the memory device 10, the anti-fuse cells 410 of the anti-fuse cell array 400, the anti-fuse cells 410 being connected to the first word line WLR1, are illustrated, for brevity of the drawing. The bit lines BL1 to BLn of the anti-fuse cells 410 may be electrically connected to the sense amplifier 430 and the register portion 440 through the bonding metal pad 302 of the cell array structure CAS and the bonding metal pad 301 of the core peripheral circuit structure CPS. The fuse data OUT1 to OUTn stored in the register portion 440 may be provided to the redundancy logic circuit 26 and the TMRS 27 through a bus and/or signal lines 600 formed in the core peripheral circuit structure CPS. The redundancy logic circuit 26 may perform a repair operation so that a redundancy row address may be selected, instead of a defective row address, and may perform a repair operation so that a redundancy column address may be selected, instead of a defective column address. The TMRS 27 may store the information for a test operation of the memory device 10 according to the fuse data OUT1 to OUTn stored in the register portion 440.

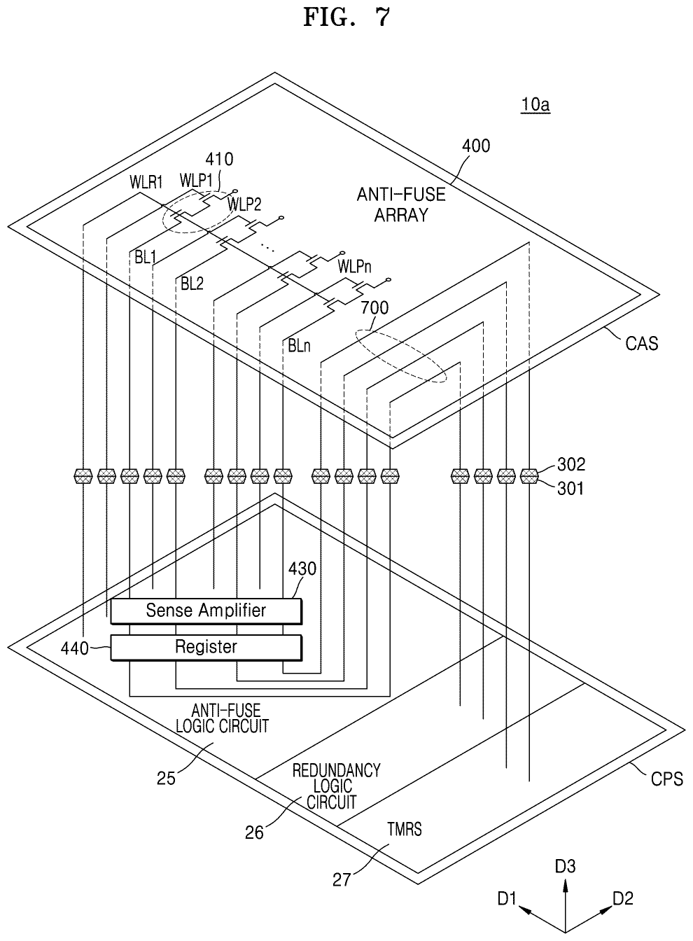

Referring to FIG. 7, the memory device 10a may be different from the memory device 10 of FIG. 6 in that the fuse data OUT1 to OUTn stored in the register portion 440 may be transmitted to a bus and/or signal lines 700 formed in the cell array structure CAS, through the bonding metal pad 301 of the core peripheral circuit structure CPS and the bonding metal pad 302 of the cell array structure CAS, and then, may be provided to the redundancy logic circuit 26 and the TMRS 27, through the bonding metal pads 302 and 301.

Due to areas occupied by the signal lines 600 (see FIG. 6) formed in the core peripheral circuit structure CPS, the core peripheral circuit structure CPS may have an increased area and the memory device 10 may have an increased chip size. In order to reduce the chip size of the memory device 10a, the fuse data OUT1 to OUTn provided by the register portion 440 of the anti-fuse logic circuit 25 may be provided to the redundancy logic circuit 26 and the TMRS 27 by detouring through the bus and/or the signal lines 700 formed in the cell array structure CAS.

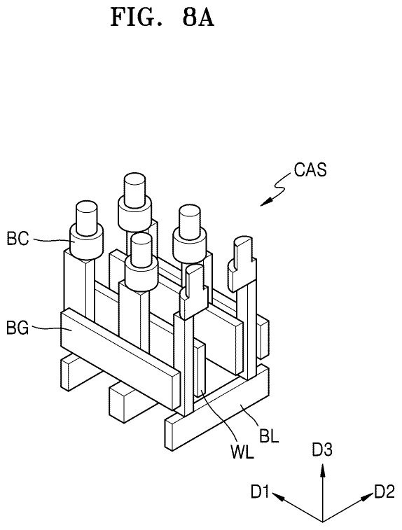

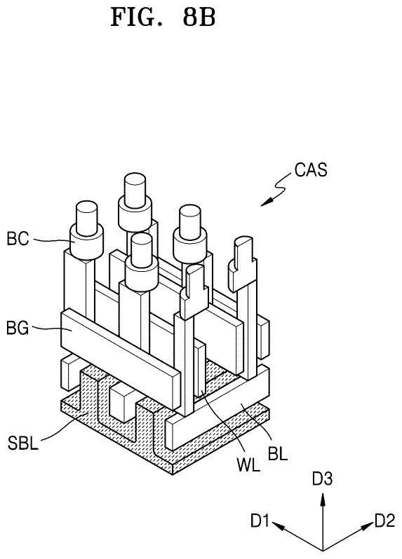

FIGS. 8A, 8B, and 9 are diagrams to describe a structure of the memory device 10, according to embodiments. FIGS. 8A and 8B are perspective views of the cell array structure CAS of the memory device 10 of FIG. 5. The cell array structure CAS of FIG. 8B shows a structure in which a shielding bit line SBL is arranged between the bit lines BL and throughout lower areas of the bit lines BL, in order to reduce coupling noise between the bit lines BL adjacent to each other in the cell array structure CAS of FIG. 8A. FIG. 9 is a cross-sectional view of the memory device 10 taken along a second direction (a D2 direction) (for example, taken along a line X1-X2 of FIG. 5).

Referring to FIGS. 8A, 8B, and 9 together, the core peripheral circuit structure CPS may include a lower substrate 310, an interlayer insulating layer 315, a plurality of circuit devices, namely, a first circuit device 312a and a second circuit device 312b, formed on the lower substrate 310, first metal layers 314a and 314b respectively connected to the plurality of circuit devices 312a and 312b, second metal layers 316a and 316b formed on the first metal layers 314a and 314b, and the bonding metal pad 301 formed on an uppermost metal layer of the core peripheral circuit structure CPS. According to an embodiment, the first metal layers 314a and 314b may include tungsten (W) having relatively high resistance, the second metal layers 316a and 316b may include copper (Cu) having relatively low resistance, and the bonding metal pad 301 may include Cu. According to an embodiment, the bonding metal pad 301 may include aluminum (Al) or W.

In this specification, only the first metal layers 314a and 314b and the second metal layers 316a and 316b are illustrated and described. However, embodiments are not limited thereto, and one or more metal layers may further be formed on the second metal layers 316a and 316b. At least one of the one or more metal layers formed above the second metal layers 316a and 316b may include aluminum, etc. having a lower resistance than Cu included in the second metal layers 316a and 316b. An interlayer insulating layer 315 may be arranged on the lower substrate 310 to cover the plurality of circuit devices 312a and 312b, the first metal layers 314a and 314b, and the second metal layers 316a and 316b and may include an insulating material, such as silicon oxide, silicon nitride, etc.

The plurality of circuit devices 312a and 312b may be connected to at least one of circuit devices included in a peripheral circuit. For convenience of explanation, the first circuit device 312a may indicate transistors included in the row decoder 28 or transistors included in the column decoder 29, and the second circuit device 312b may indicate transistors included in the control logic circuit.

In the memory device 10, the bit lines BL may be arranged on an upper substrate 320 to be apart from each other in a first direction (a D1 direction). The upper substrate 320 may indicate a corresponding element of the lower substrate 310. According to an embodiment, the upper substrate 320 may be referred to as a plate or a conductive plate. The bit lines BL may be apart from each other in the first direction (the D1 direction) and may extend in a second direction (a D2 direction) crossing the first direction (the D1 direction). Active patterns AP may be alternately arranged on each of the bit lines BL in the second direction (the D2 direction). The active patterns AP may be apart from each other by a certain distance in the first direction (the D1 direction). That is, the active patterns AP may be two-dimensionally arranged in the first direction (the D1 direction) and the second direction (the D2 direction) crossing each other. According to some embodiments, the plurality of word lines WL, the plurality of bit lines BL, and the plurality of active patterns AP may form a plurality of vertical channel transistors.

Each of the active patterns AP may have a length in the first direction (the D1 direction), a width in the second direction (the D2 direction), and a height in the third direction (the D3 direction) perpendicular to the upper substrate 320. Each of the active patterns AP may have substantially the same width. Each of the active patterns AP may have an upper surface and a lower surface opposite to each other in the third direction (the D3 direction). For example, the lower surfaces of the active patterns AP may be in contact with the bit line BL. Each of the active patterns AP may include a source area, which is adjacent to the bit line BL, a drain area, which is adjacent to a contact pattern BC, and a channel area, which is between the source area and the drain area. The channel areas of the active patterns AP may be controlled by the word lines WL and back gate electrodes BG during an operation of the memory device 10. The active patterns AP may include, for example, monocrystalline silicon (Si), in order to improve the leakage current characteristic during the operation of the memory device 10.

The back gate electrodes BG may be arranged on the bit lines BL to be apart from each other by a certain distance in the second direction (the D2 direction). The back gate electrodes BG may extend in the first direction (the D1 direction) across the bit lines BL. Each of the back gate electrodes BG may be arranged between the active patterns AP adjacent to each other in the second direction (the D2 direction). A first active pattern 191 may be arranged at a side of each of the back gate electrodes BG, and a second active pattern 192 may be arranged at the other side. The back gate electrodes BG may have a less height than the active patterns AP in a vertical direction. The back gate electrodes BG may receive a negative voltage during an operation of the memory device 10 and may increase a threshold voltage of the vertical channel transistor. This denotes that it is possible to prevent deterioration of the leakage current characteristic, due to reduction of a threshold voltage, according to a fine structure of the vertical channel transistor.

A first insulating pattern 111 may be arranged between the active patterns AP adjacent to each other in the second direction (the D2 direction). The first insulating pattern 111 may extend in the first direction (the D1 direction) in parallel with the back gate electrodes BG. A back gate insulating layer 113 may be arranged between each back gate electrode BG and each active pattern AP and between the back gate electrode BG and the first insulating pattern 111. The back gate insulating layer 113 may include vertical portions covering both side surfaces of the back gate electrode BG and a horizontal portion connecting the vertical portions. The horizontal portion of the back gate insulating layer 113 may be adjacent to the contact pattern BC more than to the bit line BL and may cover a lower surface of the back gate electrode BG. A back gate capping pattern 115 may be arranged between the bit lines BL and the back gate electrode BG. The back gate capping pattern 115 may include an insulating material, and a lower surface of the back gate capping pattern 115 may be in contact with the bit lines BL. The back gate capping pattern 115 may be arranged between the vertical portions of the back gate insulating layer 113.

The word lines WL may extend on the bit lines BL in the first direction (the D1 direction) and may be alternately arranged in the second direction (the D2 direction). A first word line 181 from among the word lines WL may be arranged at a side of the first active pattern 191, and a second word line 182 from among the word lines WL may be arranged at the other side of the second active pattern 192. Some of the first word lines 181 may be arranged between the first active patterns 191 adjacent to each other in the first direction (the D1 direction), and some of the second word lines 182 may be arranged between the second active patterns 192 adjacent to each other in the first direction (the D1 direction).

The word lines WL may be vertically apart from the bit lines BL and the contact patterns BC. From the vertical perspective, the word lines WL may be arranged between the bit lines BL and the contact patterns BC. The word lines WL adjacent to each other may have side walls facing each other. The word lines WL may have a less height than the active patterns AP in the vertical direction. The height of the word lines WL may be the same as or greater than a height of the back gate electrodes BG in the third direction (the D3 direction).

Gate insulating layers 160 may be arranged between the word lines WL and the active patterns AP. The gate insulating layers 160 may extend in the first direction (the D1 direction) in parallel with the word lines WL. The gate insulating layer 160 may cover a side surface of the first active pattern 191 and the other surface of the second active pattern 192. The gate insulating layers 160 may have substantially the same thickness. A second insulating pattern 141 may be arranged between the gate insulating layer 160 and the contact patterns BC. For example, the second insulating pattern 141 may include silicon oxide. A first etch stop layer 131 and a second etch stop layer 133 may be arranged between the active patterns AP and the second insulating pattern 141.

The word lines WL may be separated from each other by a third insulating pattern 151 on the gate insulating layer 160. The third insulating pattern 151 may extend in the first direction (the D1 direction) between the word lines WL. A first capping layer 153 may be arranged between the third insulating pattern 151 and the word lines WL. The first capping layers 153 may have substantially the same thickness. The third insulating pattern 151 may include a third vertical pattern 151A and a third horizontal pattern 151B.

The contact patterns BC may pass through a third etch stop layer 210 and an interlayer insulating layer 220 and may be in contact with the active patterns AP, respectively. In other words, the contact patterns BC may be in contact with the drain areas of the active patterns AP, respectively. A lower width of the contact patterns BC may be greater than an upper width of the contact patterns BC. The contact patterns BC adjacent to each other may be separated from each other by isolation insulating patterns 230. Each of the contact patterns BC may have various shapes, such as a circular shape, an oval shape, a rectangular shape, a square shape, a diamond shape, a hexagonal shape, etc. in the planar perspective. Landing pads LP may be arranged on the contact patterns BC.

The isolation insulating patterns 230 may be arranged between the landing pads LP. In the planar perspective, the landing pads LP may be arranged in a matrix shape in the first direction (the D1 direction) and the second direction (the D2 direction). Upper surfaces of the landing pads LP may be substantially coplanar with upper surfaces of the isolation insulating patterns 230. A fourth etch stop layer 240 may be formed on the isolation insulating patterns 230.

Data storage patterns DSP may be arranged on the landing pads LP. The data storage patterns DSP may be electrically connected to the active patterns AP, respectively. The data storage patterns DSP may be arranged in a matrix shape in the first direction (the D1 direction) and the second direction (the D2 direction). The data storage patterns DSP may completely overlap or partially overlap the landing pads LP. The data storage patterns DSP may be in contact with the entire upper surface or a partial upper surface of the landing pads LP. An upper insulating layer 260 may be arranged on the data storage patterns DSP, and cell contact plugs PLG may be in contact with a plate electrode 255 by passing through the upper insulating layer 260.

According to some embodiments, the data storage patterns DSP may correspond to the cell capacitor CC (see FIG. 4) and may include a capacitor dielectric layer 253 arranged between storage electrodes 251 and the plate electrode 255. In this case, the storage electrode 251 may be directly in contact with the landing pad LP, and the storage electrode 251 may have various shapes, such as a circular shape, an oval shape, a rectangular shape, a square shape, a diamond shape, a hexagonal shape, etc. in the planar perspective.

According to some embodiments, the data storage patterns DSP may be variable resistance patterns which may be switched between two resistance states according to an electrical pulse applied to a memory element. For example, the data storage patterns DSP may include a phase-change material having a crystalline state changing according to the amount of current, a perovskite compound, a transition metal oxide, a magnetic material, a ferromagnetic material, an antiferromagnetic material, etc. but are not limited thereto. According to a material layer of the data storage patterns DSP, the memory device 10 may be realized as a resistive memory, such as a phase change random-access memory (PRAM), a magnetic random-access memory (MRAM), a resistive random-access memory (RRAM), etc.

The shielding bit line SBL may be arranged between the bit lines BL and throughout lower areas of the bit lines BL. The shielding bit line SBL may reduce coupling noise between the bit lines BL adjacent to each other. For example, the shielding bit line SBL may include a shielding structure including a conductive material. First line insulating layers 173 may be apart from each other in the first direction (the D1 direction) and may extend in the second direction (the D2 direction). The first line insulating layers 173 may be in contact with facing side walls of the bit lines BL adjacent to each other and may be formed to be separated from each other in the first direction (the D1 direction). A second line insulating layer 325 may surround a lower surface and side surfaces of the shielding bit line SBL and may be formed to fill the space of (between) the shielding bit line(s) SBL.

A through electrode 322 may be in contact with a metal layer 318b by passing through the upper substrate 320 and may extend long in the third direction (the D3 direction) up to the bonding metal pad 302 formed on the uppermost metal layer of the core peripheral circuit structure CPS. According to the embodiment, only the metal layers 318a and 318b are illustrated and described. However, embodiments are not limited thereto, and one or more metal layers may further be formed on the metal layers 318a and 318b. The shielding bit line SBL may be electrically connected to the second circuit device 312b of the control logic circuit through the bonding metal pad 302 of the cell array structure CAS and the bonding metal pad 301 of the core peripheral circuit structure CPS. The shielding bit line SBL may be controlled by the control logic circuit.

According to some embodiments, the bonding metal pad 302 of the cell array structure CAS and the bonding metal pad 301 of the core peripheral circuit structure CPS may be connected to each other by an electrical or a physical bonding method. When the bonding metal pads 301 and 302 include Cu, the bonding method may be a Cu—Cu bonding method. As another example, the bonding metal pads 301 and 302 may also include Al or W.

Each of the word lines WL may be electrically or physically connected to the metal layer 318a of the cell array structure CAS, and the metal layer 318a of the cell array structure CAS may be in contact with the bonding metal pad 301. Each of the word lines WL may be electrically connected to the first circuit device 312a of the row decoder 28 through the bonding metal pad 302 of the cell array structure CAS and the bonding metal pad 301 of the core peripheral circuit structure CPS. Each of the bit lines BL may be electrically or physically connected to the metal layer 318a of the cell array structure CAS, and the metal layer 318a of the cell array structure CAS may be in contact with the bonding metal pad 301. Each of the bit lines BL may be electrically connected to the first circuit device 312a of the sense amplifier circuit through the bonding metal pad 302 of the cell array structure CAS and the bonding metal pad 301 of the core peripheral circuit structure CPS.

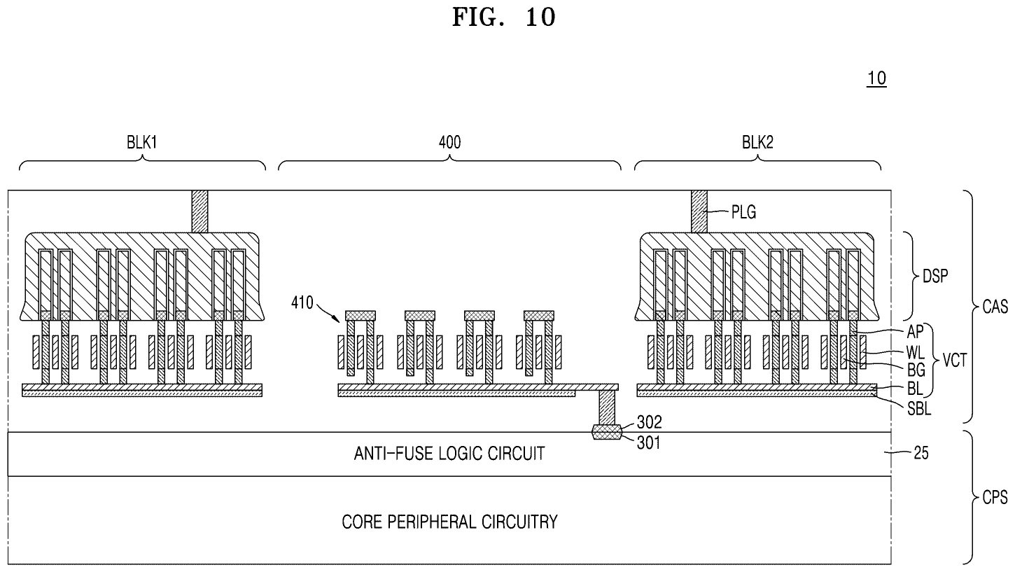

FIGS. 10 and 11 are diagrams to describe the anti-fuse cell 410 according to embodiments.

Referring to FIG. 10, in the memory device 10, memory cells including the data storage pattern DSP, the word line WL, the back gate electrode BG, the active pattern AP, the bit line BL, and the shielding bit line SBL may be arranged in each of an area of the first memory block BLK1 and an area of the second memory block BLK2 of the cell array structure CAS. The word line WL, the active pattern AP, and the bit line BL may form a vertical channel transistor VCT. The active pattern AP of the vertical channel transistor VCT in the first and second memory blocks BLK1 and BLK2 may include a first type conductive material, for example, an N-type conductive material.

The anti-fuse device 401 and the selection transistor 402 of the anti-fuse cells 410 may be formed in an area of the anti-fuse cell array 400 of the cell array structure CAS, in a process in which the vertical channel transistor VCT of the first and second memory blocks BLK1 and BLK2 is formed. That is, each of the anti-fuse cells 410 in the area of the anti-fuse cell array 400 may be formed to have the same shape as the vertical channel transistor VCT. Thus, the anti-fuse device 401 of each of the anti-fuse cells 410 may be indicated as the same pattern as the vertical channel transistor VCT.

Referring to FIG. 11, in the memory device 10b, memory cells including a first semiconductor pattern 120, the bit line BL, the word line WL, and a cell capacitor CAP (including portions EL2 and EL1) may be arranged in each of the area of the first memory block BLK1 and the area of the second memory block BLK2. The first semiconductor pattern 120, the bit line BL, and the word line WL may form a lateral channel transistor. The anti-fuse device 401 and the selection transistor 402 of the anti-fuse cells 410 may be formed in an area of the anti-fuse cell array 400 of the cell array structure CAS, in a process in which the lateral channel transistor of the first and second memory blocks BLK1 and BLK2 is formed. That is, each of the anti-fuse cells 410 in the area of the anti-fuse cell array 400 may be formed to have the same shape as the lateral channel transistor.

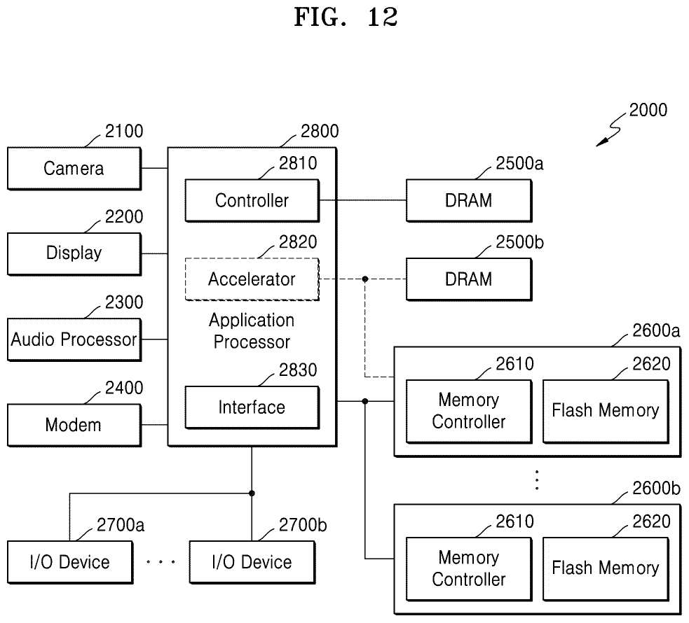

FIG. 12 is a block diagram of a system 2000 of an electronic device including a memory device according to embodiments.

Referring to FIG. 12, the system 2000 may include a camera 2100, a display 2200, an audio processor 2300, a modem 2400, dynamic random-access memories (DRAMs) 2500a and 2500b, flash memories 2600a and 2600b, input/output (I/O) devices 2700a and 2700b, and an application processor (AP) 2800. The system 2000 may be implemented by a laptop computer, a mobile terminal, a smart phone, a table personal computer (PC), a wearable device, a health care device, or an Internet of Things (IoT) device. Also, the system 2000 may be implemented by a server or a PC.

The camera 2100 may capture a still image or a video, store the captured image/video data, or transmit the captured image/video data to the display 2200, according to control by a user. The audio processor 2300 may process audio data included in the contents of the flash memories 2600a and 2600b or networks. The modem 2400 may modulate and transmit a signal for transmission and reception of wired/wireless data, and a receiving end may demodulate the signal to restore the original signal. The I/O devices 2700a and 2700b may include devices for providing a digital input and/or output function, such as a universal serial bus (USB), a storage, a digital camera, a secure digital (SD) card, a digital versatile disc (DVD), a network adapter, a touch screen, etc.

The AP 2800 may control general operations of the system 2000. The AP 2800 may include a control block 2810, an accelerator block or an accelerator chip 2820, and an interface block 2830. The AP 2800 may control the display 2200 to display a portion of the contents stored in the flash memories 2600a and 2600b. When a user input is received through the I/O devices 2700a and 2700b, the AP 2800 may perform a control operation corresponding to the user input. The AP 2800 may include an accelerator block, which is an exclusive circuit for artificial intelligence (AI) data calculation, or an accelerator chip 2820 may be separately provided from the AP 2800. The DRAM 2500b may be additionally mounted in the accelerator block or the accelerator chip 2820. The accelerator may be a functional block specialized in a specific function of the AP 2800 and may include a GPU, which is a functional block specialized in graphics data processing, a neural processing unit (NPU), which is a block specialized in AI calculations and inference, and a data processing unit (DPU), which is a block specialized in data transmission. According to an embodiment, an image captured by a user by using the camera 2100 may be signal processed and stored in the DRAM 2500b, and the accelerator block or the accelerator chip 2820 may perform AI data calculation for recognizing data by using data stored in the DRAM 2500b and the function for inference.

The system 2000 may include the plurality of DRAMs 2500a and 2500b. The AP 2800 may control the DRAMs 2500a and 2500b according to a command and an MRS complying with the JEDEC standards or may perform communication by setting a DRAM interface regulation to use a business-exclusive function related to low voltage/high speed/reliability and a cyclic redundancy check (CRC)/error correction code (ECC) function. For example, the AP 2800 may communicate with the DRAM 2500a by using an interface according to the JEDEC standards, such as LPDDR4, LPDDR5, etc., and may communicate with the DRAM 2500b by setting a new DRAM interface regulation to control the DRAM 2500b for the accelerator that has a greater band width than the DRAM 2500a.

FIG. 12 illustrates only the DRAMs 2500a and 2500b. However, the disclosure is not limited thereto, and any one of the memories, such as phase-change random access memory (PRAM), static random-access memory (SRAM), magneto-resistive random access memory (MRAM), resistive random access memory (RRAM), ferroelectric random access memory (FRAM), or hybrid random access memory (RAM), that satisfies conditions about a bandwidth, a response rate, and a voltage with respect to the AP 2800 or the accelerator chip 2820, may be used. The DRAMs 2500a and 2500b may have a relatively less latency and a relatively less bandwidth than the I/O devices 2700a and 2700b or the flash memories 2600a and 2600b. The DRAMs 2500a and 2500b may be initialized at a power on time point of the system 2000, and loaded with an operating system and application data, the DRAMs 2500a and 2500b may be used as a temporary storage of the operating system and the application data or as an execution space of various software codes.

In the DRAMs 2500a and 2500b, the four fundamental arithmetic operations of addition/subtraction/multiplication/di-vision, a vector operation, an address operation, or a fast Fourier transform (FET) operation may be performed. Also, in the DRAMs 2500a and 2500b, a function for inference may be performed. Here, the inference may be performed by a deep learning algorithm using an artificial neural network. The deep learning algorithm may include a training operation in which a model is trained by using various data and an inference operation in which the trained model recognizes data.

The system 2000 may include a plurality of storages or the plurality of flash memories 2600a and 2600b having greater capacities than the DRAMs 2500a and 2500b. The accelerator block or the accelerator chip 2820 may perform the training operation and the AI data calculation by using the flash memories 2600a and 2600b. According to an embodiment, the flash memories 2600a and 2600b may include a memory controller 2610 and a flash memory device 2620 and may use an operation device provided in the memory controller 2610 to perform, with relatively increased efficiency, the training operation and the inference AI data calculation performed by the AP 2800 and/or the accelerator chip 2820. The flash memories 2600a and 2600b may store a photograph captured by the camera 2100 or store data transmitted from a data network. For example, augmented reality (AR)/virtual reality (VR), high definition (HD), or ultra-high definition (UHD) contents may be stored.

In the system 2000, the DRAMs 2500a and 2500b may include a memory device described with reference to FIGS. 1 to 11. The memory device may include a core peripheral circuit structure and a cell array structure, wherein the core peripheral circuit structure may include a first bonding metal pad and the cell array structure may be arranged on the core peripheral circuit structure to vertically overlap the core peripheral circuit structure and may include a second bonding metal pad in contact with the first bonding metal pad. The cell array structure may include a memory cell array area including a plurality of memory blocks and an anti-fuse cell array area including a plurality of anti-fuse cells, the anti-fuse cell array area being arranged in other areas than the memory cell array area. The memory cell array area may include a plurality of word lines extending in a first horizontal direction and a plurality of bit lines extending in a second horizontal direction intersecting the first horizontal direction, and may include a plurality of cell structures including a plurality of vertical channel transistor structures arranged on each of the plurality of bit lines and a plurality of capacitor structures connected to the plurality of vertical channel transistor structures, respectively. Each of the anti-fuse cells in the anti-fuse cell array area may include an anti-fuse device and a selection transistor, and the anti-fuse device may have the same shape as the plurality of vertical channel transistor structures or may have a different shape from the plurality of vertical channel transistor structures, for example, a shape of a lateral channel transistor. The core peripheral circuit structure may include a repair circuit configured to sense and amplify information programmed in each of the anti-fuse cells and to output the sensed and amplified information as first fuse data and second fuse data, and the repair circuit may perform a repair operation of replacing a defective memory cell in the memory cell array area with a redundancy memory cell, based on the first fuse data. The core peripheral circuit structure may further include a TMRS configured to store test options for a test operation of the memory device based on the second fuse data. According to the memory device, an anti-fuse cell array, which is included in the repair circuit, may be arranged in an area other than the memory cell array area in the cell array structure, and thus, the repair circuit may have a reduced area in the core peripheral circuit structure, so that a chip size of the memory device may be reduced. Memory devices as described above may have improved yield rate and reliability.

While example embodiments have been particularly shown and described, it will be understood that various changes in form and details may be made to the embodiments without departing from the spirit and scope of the following claims.

What is claimed is:

1. A memory device comprising:
a core peripheral circuit structure comprising a first bonding metal pad; and
a cell array structure above and vertically overlapping the core peripheral circuit structure, the cell array structure comprising a second bonding metal pad contacting the first bonding metal pad,
wherein the cell array structure comprises:
a memory cell array area comprising a plurality of memory blocks; and
an anti-fuse cell array area comprising a plurality of anti-fuse cells, the anti-fuse cell array area being in a different area from the memory cell array area,
wherein the core peripheral circuit structure further comprises a repair circuit connected to first signal lines and the plurality of anti-fuse cells of the anti-fuse cell array area, and
wherein the repair circuit comprises:
an anti-fuse logic circuit configured to control each anti-fuse cell of the plurality of anti-fuse cells to be programmed, receive information programmed in the plurality of anti-fuse cells through the first and second bonding metal pads connected to the plurality of anti-fuse cells, and output fuse data; and
a redundancy logic circuit configured to receive first fuse data through the first signal lines connected to the anti-fuse logic circuit and perform, based on the first fuse data, a repair operation of replacing a defective memory cell in the memory cell array area with a redundancy memory cell.

2. The memory device of claim 1, wherein the anti-fuse logic circuit comprises:
a level shifter configured to generate a high voltage for programming each anti-fuse cell of the plurality of anti-fuse cells by changing a resistance state of each anti-fuel cell of the plurality of anti-fuse cells;
a sense amplifier configured to sense and amplify the information programmed in each anti-fuse cell of the plurality of anti-fuse cells and output the information as the fuse data; and
a register portion configured to store the fuse data.

3. The memory device of claim 1, wherein the memory cell array area further comprises:
a plurality of word lines extending in a first horizontal direction;
a plurality of bit lines extending in a second horizontal direction intersecting the first horizontal direction;
a plurality of cell structures comprising a plurality of vertical channel transistor structures arranged on each of the plurality of bit lines; and
a plurality of capacitor structures connected to the plurality of vertical channel transistor structures, respectively,
wherein each anti-fuse cell of the plurality of anti-fuse cells of the anti-fuse cell array area comprises an anti-fuse device and a selection transistor, and
wherein the anti-fuse device and the selection transistor have a shape that is the same as a shape of each of the plurality of vertical channel transistor structures.

4. The memory device of claim 3, wherein the memory cell array area further comprises a shielding bit line between the plurality of bit lines and below the plurality of bit lines.

5. The memory device of claim 1, wherein the memory cell array area further comprises:
a plurality of first semiconductor patterns extending in a first horizontal direction;
a plurality of word lines surrounding each of the plurality of first semiconductor patterns and extending in a second horizontal direction intersecting the first horizontal direction;
a plurality of bit lines connected to a first end of each of the plurality of first semiconductor patterns and extending in a third direction perpendicular to the first and second horizontal directions; and
a plurality of cell structures comprising a plurality of lateral channel transistor structures and a plurality of capacitor structures connected to the plurality of lateral channel transistor structures, respectively, the plurality of lateral channel transistor structures being connected to each of the plurality of bit lines,
wherein each anti-fuse cell of the plurality of anti-fuse cells of the anti-fuse cell array area comprises an anti-fuse device and a selection transistor, and
wherein the anti-fuse device and the selection transistor have a shape that is the same as a shape of each of the plurality of lateral channel transistor structures.

6. The memory device of claim 1, wherein the core peripheral circuit structure further comprises a test mode register set (TMRS) connected to the anti-fuse logic circuit, and
wherein the TMRS is configured to receive second fuse data through the first signal lines connected to the anti-fuse logic circuit and store, based on the second fuse data, test options for a test operation of the memory device.

7. A memory device comprising:
a core peripheral circuit structure comprising a first bonding metal pad; and
a cell array structure above the core peripheral circuit structure and vertically overlapping the core peripheral circuit structure, the cell array structure comprising a second bonding metal pad contacting the first bonding metal pad,
wherein the cell array structure comprises:
first signal lines;
a memory cell array area comprising a plurality of memory blocks; and
an anti-fuse cell array area comprising a plurality of anti-fuse cells, the anti-fuse cell array area being in a different area from the memory cell array area,
wherein the core peripheral circuit structure further comprises a repair circuit connected to second signal lines and the plurality of anti-fuse cells, and
wherein the repair circuit comprises:
an anti-fuse logic circuit configured to control each anti-fuse cell of the plurality of anti-fuse cells to be programmed, receive information of the plurality of anti-fuse cells through the first and second bonding metal pads connected to the plurality of anti-fuse cells and output fuse data, and provide the fuse data to the first signal lines of the cell array structure through the first and second bonding metal pads; and
a redundancy logic circuit configured to receive first fuse data through the first and second bonding metal pads connected to the first signal lines of the cell array structure and the second signal lines of the core peripheral circuit structure and perform, based on the first fuse data, a repair operation of replacing a defective memory cell in the memory cell array area with a redundancy memory cell.

8. The memory device of claim 7, wherein the anti-fuse logic circuit comprises:
a level shifter configured to generate a high voltage for programming each anti-fuse cell of the plurality of anti-fuse cells by changing a resistance state;
a sense amplifier configured to sense and amplify the information of the plurality of anti-fuse cells and output the information as the fuse data; and
a register portion configured to store the fuse data.

9. The memory device of claim 7, wherein the memory cell array area further comprises:
a plurality of word lines extending in a first horizontal direction of a semiconductor substrate;
a plurality of bit lines extending in a second horizontal direction intersecting the first horizontal direction; and
a plurality of cell structures comprising a plurality of vertical channel transistor structures and a plurality of capacitor structures connected to the plurality of vertical channel transistor structures, respectively, the plurality of vertical channel transistor structures being arranged on each of the plurality of bit lines,
wherein each anti-fuse cell of the plurality of anti-fuse cells of the anti-fuse cell array area comprises an anti-fuse device and a selection transistor, and
wherein the anti-fuse device and the selection transistor have a shape that is the same as a shape of each of the plurality of vertical channel transistor structures.

10. The memory device of claim 9, wherein the memory cell array area further comprises a shielding bit line between the plurality of bit lines and below the plurality of bit lines.

11. The memory device of claim 7, wherein the memory cell array area further comprises:
a plurality of first semiconductor patterns extending in a first horizontal direction;
a plurality of word lines surrounding each of the plurality of first semiconductor patterns and extending in a second horizontal direction intersecting the first horizontal direction;
a plurality of bit lines connected to a first end of each of the plurality of first semiconductor patterns and extending in a third direction perpendicular to the first and second horizontal directions; and
a plurality of cell structures comprising a plurality of lateral channel transistor structures and a plurality of capacitor structures connected to the plurality of lateral channel transistor structures, respectively, the plurality of lateral channel transistor structures being connected to each of the plurality of bit lines,
wherein each anti-fuse cell of the plurality of anti-fuse cells of the anti-fuse cell array area comprises an anti-fuse device and a selection transistor, and
wherein the anti-fuse device and the selection transistor have a shape that is the same as a shape of each of the plurality of lateral channel transistor structures.

12. The memory device of claim 7, wherein the core peripheral circuit structure further comprises a test mode register set (TMRS) connected to the anti-fuse logic circuit, and wherein the TMRS is configured to receive second fuse data through the second signal lines and store, based on the second fuse data, test options for a test operation of the memory device.

13. A memory device comprising:
a core peripheral circuit structure comprising a first bonding metal pad; and
a cell array structure arranged above the core peripheral circuit structure and vertically overlapping the core peripheral circuit structure, the cell array structure comprising a second bonding metal pad contacting the first bonding metal pad,
wherein the cell array structure comprises:
a memory cell array area comprising a plurality of memory blocks; and
an anti-fuse cell array area comprising a plurality of anti-fuse cells and in a different area from the memory cell array area, and
wherein the core peripheral circuit structure further comprises a test mode register set (TMRS) configured to store, based on first fuse data stored in the plurality of anti-fuse cells of the anti-fuse cell array area, test options for a test operation of the memory device.

14. The memory device of claim 13, wherein the core peripheral circuit structure further comprises a repair circuit configured to sense and amplify information programmed in each anti-fuse cell of the plurality of anti-fuse cells and output the sensed and amplified information as the first fuse data and second fuse data.

15. The memory device of claim 14, wherein the TMRS is further configured to receive the first fuse data through first signal lines of the core peripheral circuit structure connected to the repair circuit.

16. The memory device of claim 14, wherein the repair circuit is further configured to provide the first fuse data and the second fuse data to first signal lines of the cell array structure through the first and second bonding metal pads, and
wherein the TMRS is further configured to receive the first fuse data through the first and second bonding metal pads connected to the first signal lines of the cell array structure and second signal lines of the core peripheral circuit structure.

17. The memory device of claim 14, wherein the repair circuit is further configured to perform, based on the second fuse data, a repair operation of replacing a defective memory cell in the memory cell array area with a redundancy memory cell.

18. The memory device of claim 13, wherein the memory cell array area further comprises:
a plurality of word lines extending in a first horizontal direction;
a plurality of bit lines extending in a second horizontal direction intersecting the first horizontal direction; and
a plurality of cell structures comprising a plurality of vertical channel transistor structures and a plurality of capacitor structures connected to the plurality of vertical channel transistor structures, respectively, the plurality of vertical channel transistor structures being arranged on each of the plurality of bit lines,
wherein each anti-fuse cell of the plurality of anti-fuse cells of the anti-fuse cell array area comprises an anti-fuse device and a selection transistor, and
wherein the anti-fuse device and the selection transistor have a shape that is the same as a shape of each of the plurality of vertical channel transistor structures.

19. The memory device of claim 18, wherein the memory cell array area further comprises a shielding bit line between the plurality of bit lines and below the plurality of bit lines.

20. The memory device of claim 13, wherein the memory cell array area further comprises:
a plurality of first semiconductor patterns extending in a first horizontal direction;
a plurality of word lines surrounding each of the plurality of first semiconductor patterns and extending in a second horizontal direction intersecting the first horizontal direction;
a plurality of bit lines connected to a first end of each of the plurality of first semiconductor patterns and extending in a third direction perpendicular to the first and second horizontal directions; and
a plurality of cell structures comprising a plurality of lateral channel transistor structures and a plurality of capacitor structures connected to the plurality of lateral channel transistor structures, respectively, the plurality of lateral channel transistor structures being connected to each of the plurality of bit lines,
wherein each anti-fuse cell of the plurality of anti-fuse cells of the anti-fuse cell array area comprises an anti-fuse device and a selection transistor, and
wherein the anti-fuse device and the selection transistor have a shape that is the same a shape of each of the plurality of lateral channel transistor structures.
